(19) United States
(12) Patent Application Publication
(10) Pub. No.: US 2004/0199852 A1
(43) Pub. Date: Oct. 7, 2004

(54) Optical information recording medium and data recording apparatus thereon

(75) Inventors: Sung-hee Hwang, Seoul (KR); Yoon-woo Lee, Gyeonggi-do (KR); Sung-hyu Han, Seoul (KR); Sang-hyun Ryu, Gyeonggi-do (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., Ltd., Suwon-si (KR)

(21) Appl. No.: 10/828,297

(22) Filed: Apr. 21, 2004

Related U.S. Application Data
(63) Continuation of application No. 10/124,366, filed on Apr. 18, 2002.
(60) Provisional application No. 60/284,878, filed on Apr. 20, 2001.

(30) Foreign Application Priority Data
Apr. 20, 2001 (KR) 2001-21521

(51) Int. Cl. H03M 13/00

(52) U.S. Cl. 714/758

(57) ABSTRACT

An optical information recording medium, a data recording apparatus, a data recording method used by the recording apparatus, and a data reproducing apparatus are provided, in which the optical information recording medium includes data provided in one or more recording blocks. A recording block of the optical information recording medium is generated by alternately arranging identifiers from ones of error correction code (ECC) blocks in the recording block, wherein each ECC block comprises a plurality of sectors having corresponding identifiers.

### CROSS-REFERENCE TO RELATED APPLICATIONS

This application is a continuation application of application Ser. No. 10/124,366 filed Apr. 18, 2002, now pending claims the benefit of U.S. Provisional Application No. 60/284,878 filed on Apr. 20, 2001 and Korean Patent Application No. 2001-21521 filed on Apr. 20, 2001, in the Korean Industrial Property Office, the disclosure of which is incorporated herein by reference.

### BACKGROUND OF THE INVENTION

1. Field of the Invention

The present invention relates to error correction, and more particularly, to an optical information recording medium, a data recording apparatus, and a data recording method used by the data recording apparatus which are capable of recording high density data, and a reproducing apparatus capable of reproducing high density data.

2. Description of the Related Art

Digital broadcasting will soon be commonly used in many countries of the world. However, current digital versatile discs (DVDs) have a capacity of 4.7-10 gigabytes, and thus a two-hour movie (about 25 gigabytes) which is received-via digital broadcasting cannot be recorded on a disc. As a result, a high density recording medium to record a digital broadcast having the size of a movie is required.

A method to reduce the size of a laser beam used in recording and/or reading data is a representative example of a method to increase recording density. The smaller the radius of the laser beam the more densely an information track in which data is recorded can be formed, thereby increasing recording density. However, if only the radius of the laser beam is decreased, the quantity of light used in recording and/or reading data is also reduced, and the effect caused by damage or dust occurring on the surface of the disc is relatively increased. That is, an error generation rate in recording and/or reading data is increased.

### SUMMARY OF THE INVENTION

Accordingly, it is an aspect of the present invention to provide an optical information recording medium, a data recording apparatus, and a data recording method used by the apparatus, which have higher error correction rates in recording and/or reading data.

It is another aspect of the present invention to provide an optical information recording medium, a data recording apparatus, and a data recording method used by the apparatus which are capable of searching main data at a high speed and have lower error rates.

It is yet another aspect of the present invention to provide an optical information recording medium, a data recording apparatus, and a data recording method used by the apparatus, which are compatible with the format of a conventional digital versatile disc (DVD) and have higher error correction rates.

Additional aspects and/or advantages of the invention will be set forth in part in the description which follows and, in part, will be obvious from the description, or may be learned by practice of the invention.

To achieve the above and/or other aspects of the present invention, there is provided an optical information recording medium comprising data included in one or more recording blocks, wherein, for a recording block of the optical information recording medium, each of error correction code (ECC) blocks comprises a plurality of sectors having corresponding identifiers, and the identifiers from ones of the ECC blocks are alternately arranged in the recording block.

According to an aspect of the invention, the recording blocks are modulated by a predetermined modulation method and recorded. According to another aspect, the identifiers from the ones of the ECC blocks are alternately and equally extracted and arranged at predetermined intervals, and ECC-encoded main data, which are included in the sectors corresponding to the arranged identifiers, are interleaved.

According to still another aspect of the invention, the ECC-encoded main data are interleaved in units of one or more rows or in units of at least a part of the sectors.

To achieve the above and/or other aspects of the present invention, there is provided another an optical information recording medium comprising data included in one or more recording blocks, wherein an identifier included in the first sector of a first error correction code (ECC) block is arranged as a first identifier, an identifier included in the first sector of a second ECC block is arranged as a second identifier, an identifier included in the second sector of the first ECC block is arranged as a third identifier, an identifier included in the second sector of the second ECC block is arranged as a fourth identifier, and identifiers included in the remaining sectors of the first and second ECC blocks are arranged with the same alternating pattern, and wherein ECC-encoded main data included in the first sectors of the first and second ECC blocks are interleaved to sequentially correspond to the first arranged identifier and the second arranged identifier, ECC-encoded main data included in the second sectors of the first and second ECC blocks are interleaved to correspond to the third and fourth arranged identifiers, and ECC-encoded main data included in the remaining sectors of the first and second ECC blocks are interleaved with the same alternating pattern.

According to an aspect of the invention, the identifiers are alternately and equally extracted and arranged at predetermined intervals, and the ECC-encoded main data are interleaved in units of one or more rows or in units of at least a part of the sectors.

To achieve the above and/or other aspects of the present invention, there is provided a method of recording main data on an optical information recording medium, the method comprising error correction code (ECC)-encoding main data to generate a plurality of ECC blocks, wherein each ECC block comprises a plurality of sectors having corresponding identifiers, and extracting and arranging the identifiers from ones of the ECC blocks to generate a recording block such that adjacent identifiers are of different EC blocks.

According to an aspect of the invention, the extracting and arranging of the identifiers comprises alternately and equally extracting and arranging the identifiers at predetermined intervals, and interleaving ECC-encoded main data included in the sectors corresponding to the arranged identifiers.

According to another aspect of the invention, interleaving ECC-encoded main data is performed in units of one or more rows or in units of at least part of the sectors.

To achieve the above and/or other aspects of the present invention, there is provided another method to record main data on an optical information recording medium, the method comprising error correction code (ECC)-encoding main data to generate first and second ECC blocks, each of the first and second ECC blocks comprising sectors and each sector having an identifier, arranging an identifier included in a first one of the sectors of the first ECC block as a first identifier, arranging an identifier included in a first one of the sectors of the second ECC block as a second identifier, arranging an identifier included in a second one of the sectors of the first ECC block as a third identifier, arranging an identifier included in a second one of the sectors of the second ECC block as a fourth identifier, and arranging identifiers included in the remaining sectors of the first and second ECC blocks with the same alternating pattern, interleaving ECC-encoded main data included in the first sectors of the first and second ECC blocks to sequentially correspond to the first arranged identifier and the second arranged identifier, interleaving ECC-encoded main data included in the second sectors of the first and second ECC blocks to correspond to the third and fourth arranged identifiers, and interleaving ECC-encoded main data included in the remaining sectors of the first and second ECC blocks with the same algorithm to generate a recording block.

According to an aspect of the invention, the identifiers are alternately and equally extracted and arranged at predetermined intervals in the identifier arranging operations, and the interleaving of the ECC-encoded main data are performed in units of one or more rows or in units of at least part of the sectors.

To achieve the above and/or other aspects of the present invention, there is provided an apparatus to record data on an optical information recording medium, the apparatus comprising an error correction code (ECC) encoder which ECC-encodes main data to generate a plurality of ECC blocks, each ECC block comprising sectors and each sector having an identifier, an interleaver which extracts and arranges the identifiers from ones of the ECC blocks to generate a recording block such that adjacent identifiers are of different ECC blocks, a modulating unit which modulates the generated recording block, and a recording unit which records the modulated recording block.

The interleaver may alternately and equally extracts and arrange the identifiers at predetermined intervals, and interleave ECC-encoded main data included in the sectors corresponding to the arranged identifiers. The interleaver may perform the interleaving in units of one or more rows or in units of at least part of the sectors.

To achieve the above and/or other aspects of the present invention, there is provided another apparatus to record data on an optical information recording medium, the apparatus comprising an error correction code (ECC) encoder to ECC-encode main data to generate first and second ECC blocks, each of the first and second ECC blocks comprises sectors and each sector including an identifier, an interleaver which arranges an identifier included in the first sector of the first ECC block as a first identifier, arranges an identifier included in the first sector of the second ECC block as a second identifier, arranges an identifier included in the second sector of the first ECC block as a third identifier, arranges an identifier included in the second sector of the second ECC block as a fourth identifier, arranging identifiers included in the remaining sectors of the first and second ECC blocks with the same algorithm, interleaves ECC-encoded main data in the first sectors of the first and second ECC blocks to sequentially correspond to the first arranged identifier and the second arranged identifier, interleaves ECC-encoded main data in the second sectors of the first and second ECC blocks to correspond to the third and fourth arranged identifiers, and interleaves ECC-encoded main data included in the remaining sectors of the first and second ECC blocks with the same algorithm to generate a recording block, a modulating unit which modulates the generated recording block, and a recording unit which records the modulated recording block.

### BRIEF DESCRIPTION OF THE DRAWINGS

These and other objects and advantages of the present invention will become apparent and more readily appreciated from the following description of the embodiments, taken in conjunction with the accompanying drawings of which:

FIGS. 1A and 1B are block diagrams of a data recording apparatus according to an embodiment of the present invention;

FIG. 2A illustrates the format of an error correction code (ECC) block for interleaving according to an embodiment of the present invention, and FIG. 2B illustrates the format of a sector of the ECC block;

FIG. 3 illustrates the format of a block generated by in-block interleaving of FIG. 2A according to the FIG. 1 embodiment of the present invention;

FIG. 4 illustrates the format of ECC blocks A and B to interleave according to an embodiment of the present invention;

FIG. 5 illustrates the format of a recording block according to an embodiment of the present invention;

FIG. 6 is an example of the recording block generated by between-block interleaving of FIG. 5 according to an embodiment of the present invention;

FIG. 7 illustrates the largest error of a recording block according to an embodiment of the present invention that can be corrected by error correction according to the present invention;

FIGS. 8A and 8B illustrate the recording block in which the largest error occurs, rearranged on the basis of the ECC blocks A and B of FIG. 7;

FIGS. 9A and 9B are block diagrams of a data reproducing apparatus according to an embodiment of the present invention;

FIG. 10 is a schematic flow chart illustrating a data recording method according to an embodiment of the present invention; and

FIG. 11 is a flow chart illustrating a data recording method according to an embodiment of the present invention.

### DETAILED DESCRIPTION OF THE PREFERRED EMBODIMENTS

Reference will now be made in detail to the embodiments of the present invention, examples of which are illustrated in the accompanying drawings, wherein like reference numerals refer to the like elements throughout. The embodiments are described below in order to explain the present invention by referring to the figures.

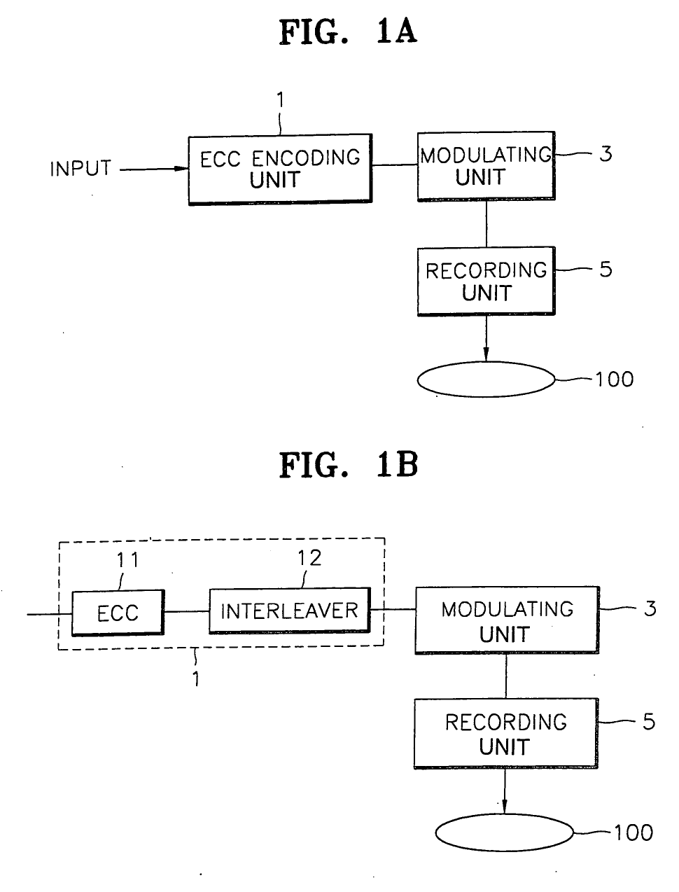

FIGS. 1A and 1B are block diagrams of a data recording apparatus according to an embodiment of the present invention. Referring to FIGS. 1A and 1B, the data recording apparatus comprises an error correction code (ECC) encoding unit 1, a modulating unit 3, and a recording unit 5. The ECC encoding unit 1 includes an ECC encoder 11 and an interleaver 12. The ECC encoder 11 encodes main data with an error-correction-code (ECC). The interleaver 12 interleaves the ECC-encoded main data according to the present invention and generates a recording block. Interleaving is done to increase error correction efficiency and is a method to physically and distributedly record contiguous main data in ECC blocks on an optical disc. Burst error can be very effectively corrected by interleaving. A more specific interleaving method will be described later.

The modulating part 3 modulates the recording block generated by the ECC encoding part 1 according to a predetermined modulating method. The modulating method used in this embodiment is eight to fourteen modulation plus (EFM+), that is, a method to modulate each byte of the recording block data into a 16 bit code word. The recording part 5 records the modulated recording block on an optical disc 100. When recording the modulated recording block on the optical disc 100, a channel bit pulse stream, which a modulated bit stream is converted into by non return to zero inversion (NRZI) coding according to the embodiment, is recorded. Here, various converting methods to record the channel bit pulse stream can be used.

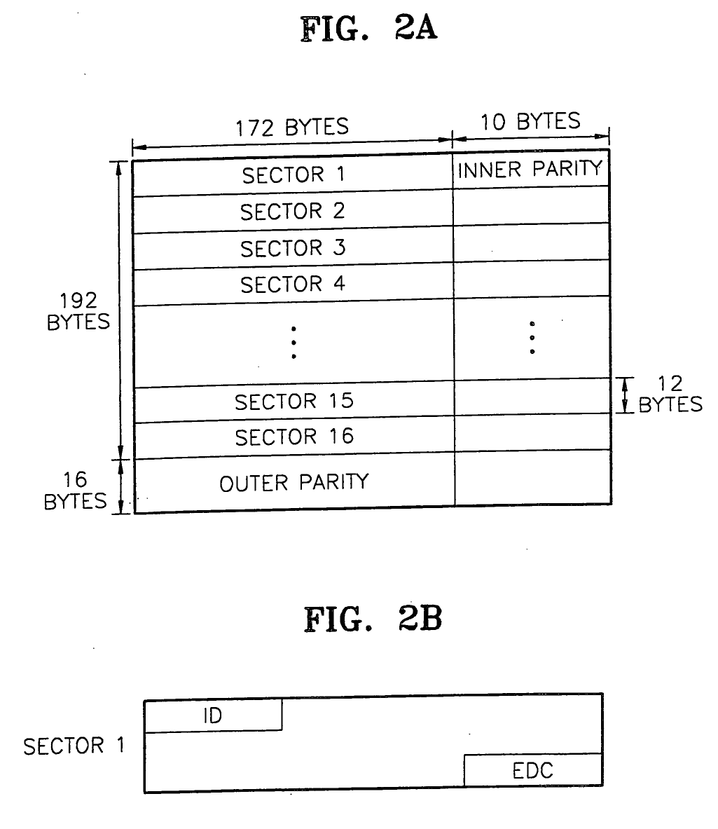

FIG. 2A illustrates the format of an error correction code (ECC) block to interleave according to an embodiment of the present invention. FIG. 2B illustrates the format of a sector of the ECC block. Referring to FIG. 2A, the ECC block includes 182 bytes of data in a row direction, and 208 bytes of data in a column direction. 172 bytes of main data and 10 bytes of an inner parity of a row-code word are arranged in a row direction, and 16 sectors and 16 bytes of an outer parity are arranged in a column direction. 12 bytes of one sector is arranged in a column direction. The row-code words can be obtained by Reed-Solomon Product coding. That is, each row is a RS(182, 172,11) code, and each column is a RS(208, 192,17) code. Here, 182 and 208 are the total size of the code words, 172 and 192 are the size of the main data, and 11 and 17 are the number of parity bytes plus one byte. Since Reed-Solomon Product coding is good at correcting multi-errors and is used in digital versatile discs (DVD), in this embodiment, Reed-Solomon Product coding is selected for compatibility with DVDs. However, the coding method used can be changed when needed. Similarly, the size of the ECC block and the number of bytes allocated to the parity can be changed.

Referring to FIG. 2B, 12 bytes of an identifier ID and 4 bytes of a parity for error detection and correction (EDC) are included in each sector. The address of the main data included in the corresponding sector is recorded in the identifier ID. Thus, the main data can be searched by the identifier ID.

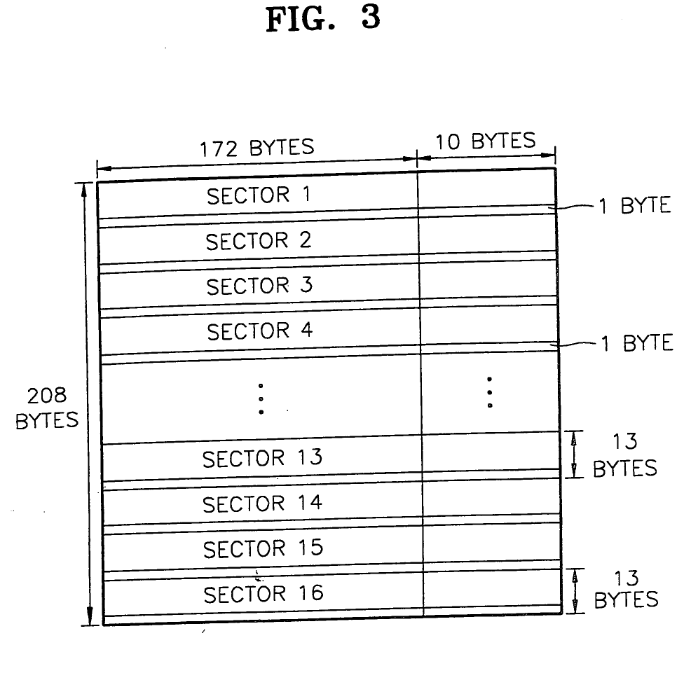

FIG. 3 illustrates the format of a block generated by in-block interleaving of FIG. 2A according to an embodiment of the present invention. Referring to FIG. 3, the ECC block is interleaved in the block according to this embodiment. In other words, 16 bytes of an outer parity is included at the end of each sector in units of one row in the same way as row-interleaving defined in a DVD format. As a result, many unbalances (caused by the difference of an outer parity block) occurring when the ECC block is recorded by the above method can be removed.

Interleaving in the block (i.e. “in-block interleaving”) used in this embodiment is performed in consideration of interchangeability with a DVD and uniformity of data included in the ECC block, but may be used as occasion demands.

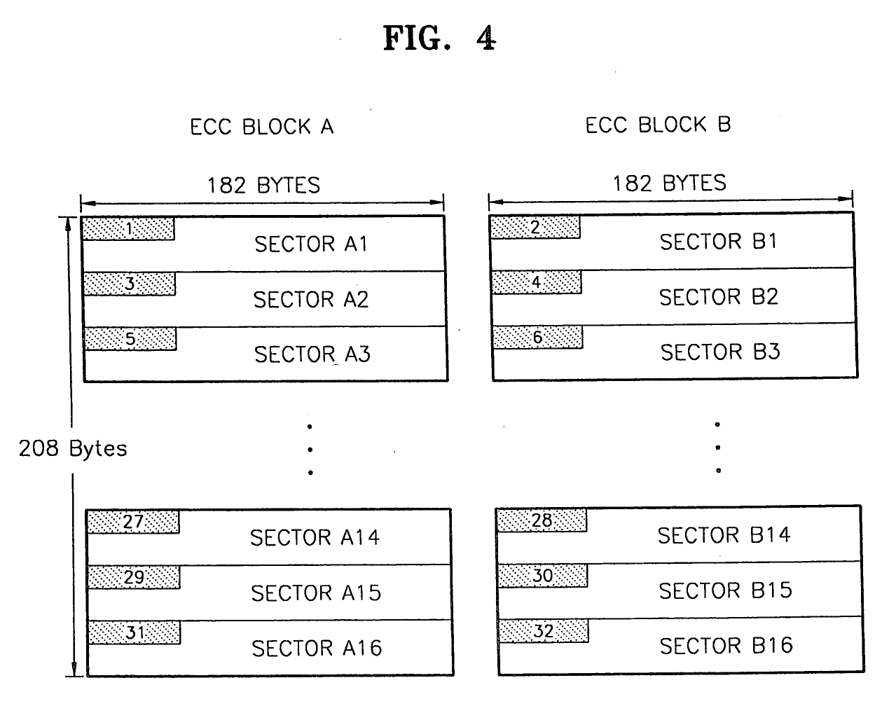

FIG. 4 illustrates the format of ECC blocks A and B to interleave according to an embodiment of the present invention. Referring to FIG. 4, as described in FIGS. 2 and 3, the ECC block A includes sector A1, . . . , sector A16, and the ECC block B includes sector B1, . . . , sector B16. An identifier ID is included in each sector. Also, main data corresponding to the arranged identifier ID are arranged in each sector. In other words, the order of arrangement of the identifier ID is the same as the order of arrangement of the sector of the main data.

Assuming that the ECC blocks A and B are interleaved in the blocks (i.e. “between blocks interleaved”) to generate one recording block, the order of arrangement of the identifier ID in the recording block is shown in FIG. 4. In other words, the identifiers of the sectors included in the ECC blocks A and B are alternately and equally extracted and arranged so that the corresponding ECC blocks are alternately selected. For example, the identifiers and ECC blocks are arranged as follows:

(1) Identifier of A1 [symbol] (2) Identifier of B1 [symbol] (3) Identifier of A2 [symbol] (4) Identifier of B2 [symbol] (5) Identifier of A3 [symbol] (6) Identifier of B3 [symbol] , . . . , z,900 (31) Identifier of A16 [symbol] (32) Identifier of B16.

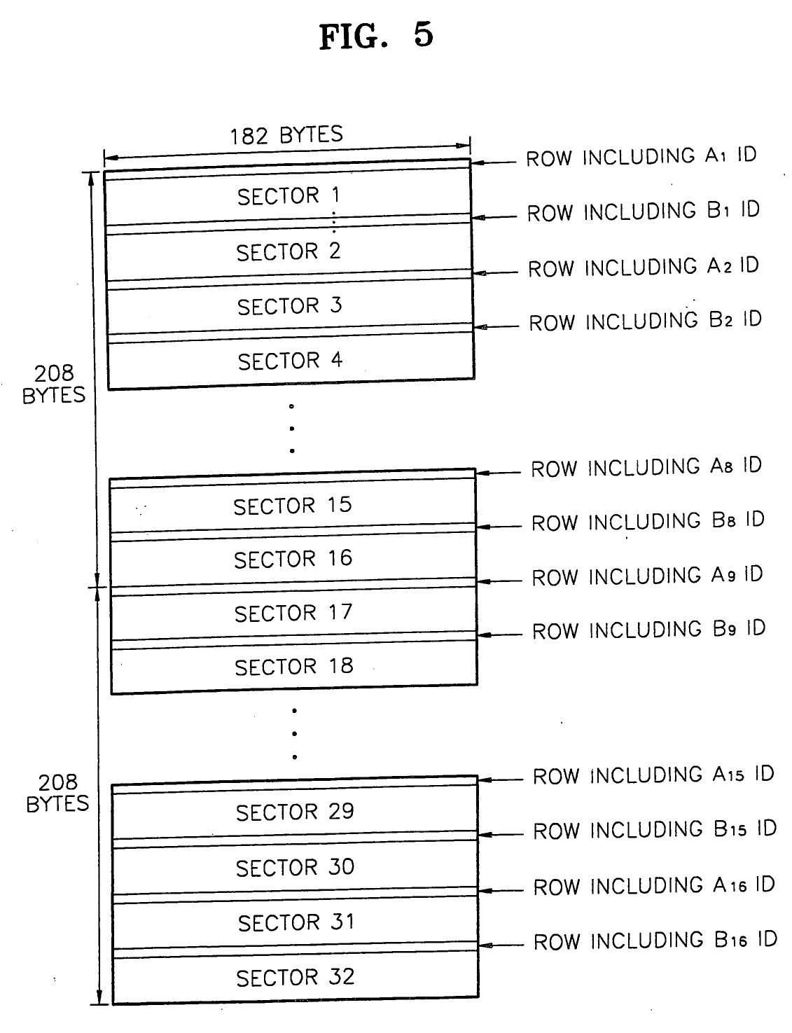

FIG. 5 illustrates the format of a recording block according to an embodiment of the present invention. Referring to FIG. 5, the recording block is obtained by interleaving in the block the ECC blocks A and B of FIG. 4. The recording block has a size of 208×2 bytes in a column direction and a size of 182 bytes in a row direction. New 32 sectors, which are generated by interleaving the 16 sectors (A1, . . . , A16) included in the ECC block A of FIG. 4 and the 16 sectors (B1, . . . , B16) included in the ECC block B of FIG. 4, are arranged in the recording block. In particular, a row-code word, in which the identifier ID of each sector is included, is in the first row of each sector. That is, the identifiers in the recording block are arranged in the order in which the identifiers of the sectors included in the ECC blocks A and B are alternately and equally extracted and arranged, as described with reference to FIG. 4.

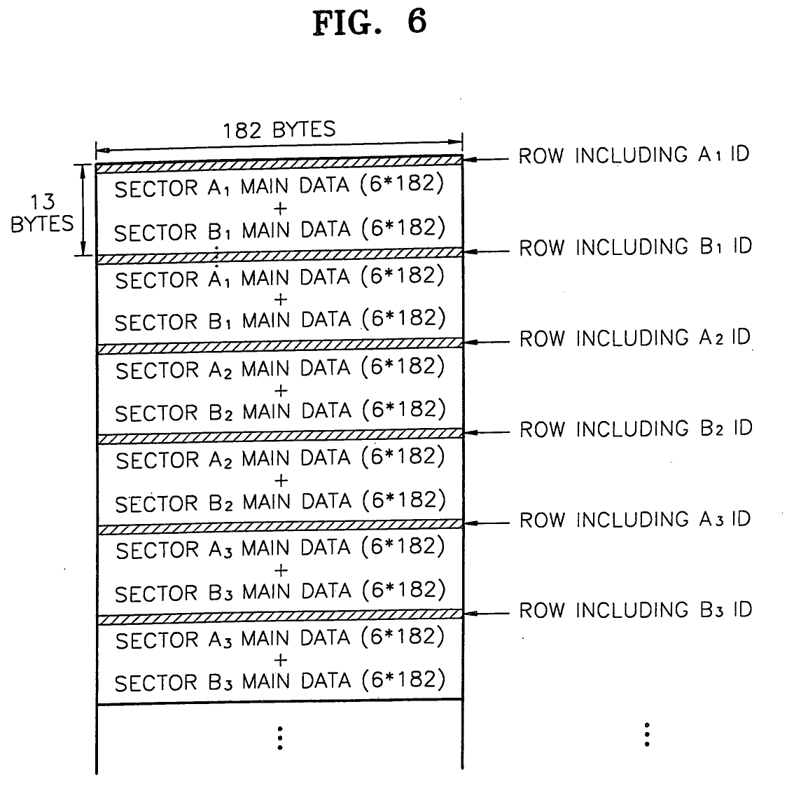

FIG. 6 is an example of the recording block generated by interleaving of FIG. 5 according to an embodiment of the present invention. Referring to FIG. 6, a row-code word including an identifier ID, row-code words (ECC-encoded main data) included in the top half of the first sector A1 of the ECC block A, and row-code words (ECC-encoded main data) included in the top half of the first sector B1 of the ECC block B are interleaved in a first sector of the recording block. There are many interleaving methods. More specifically, the ECC-encoded main data can be interleaved in units of one or more rows, or in units of at least part of the sectors.

Similarly, a row-code word including an identifier ID, row-code words (ECC-encoded main data) included in the bottom half of the first sector A1 of the ECC block A, and row-code words (ECC-encoded main data) included in the bottom half of the first sector B1 of the ECC block B are interleaved in a second sector of the recording block. The subsequent sectors are constituted by the same method.

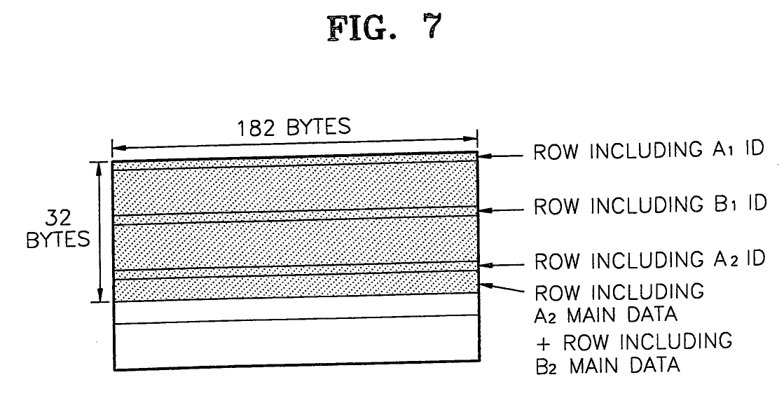

FIG. 7 illustrates the largest error that can be corrected by error correction according to an embodiment of the present invention. Since each of the ECC blocks A and B can correct an error of each 16 bytes in a column direction, as shown in FIG. 7, the largest error-generated range in which error correction is possible is a case where errors occur in 1 row including the identifier ID of a sector A1, 6 rows of the sector A1, 6 rows of a sector B1, 1 row including the identifier ID of the sector B1, the remaining 6 rows of the sector A1, the remaining 6 rows of the sector B1, 1 row including the identifier ID of a sector A2, 2 rows of the sector A2, and 3 rows of a sector B2. That is, for the ECC block A, errors occur in 1+6+6+1+2=16 rows, and for the ECC block B, errors occur in 6+1+6+3=16 rows. Thus, the sum of the rows in which errors occur is 32 rows. The size of data becomes 32×182 bytes.

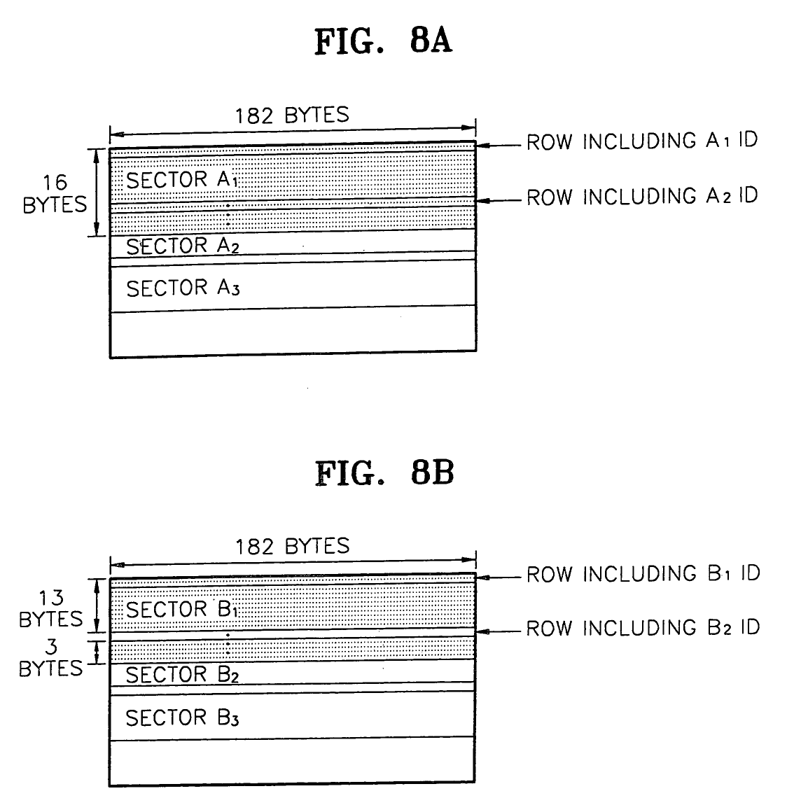

FIG. 8A and 8B illustrate the recording block in which the largest error occurs, rearranged on the basis of the ECC blocks A and B of FIG. 7. FIG. 8A is a schematic view of the ECC block A which is generated by de-interleaving the recording block in which the largest error occurs, and FIG. 8B is a schematic view of the ECC block B which is generated by de-interleaving the recording block in which the largest error occurs. The error occurring in the ECC block A is 16 bytes in total, and the error occurring in the ECC block B is also 16 bytes in total. That is, since each of the ECC blocks A and B can correct an error of each 16 bytes in a column direction, each error can be corrected.

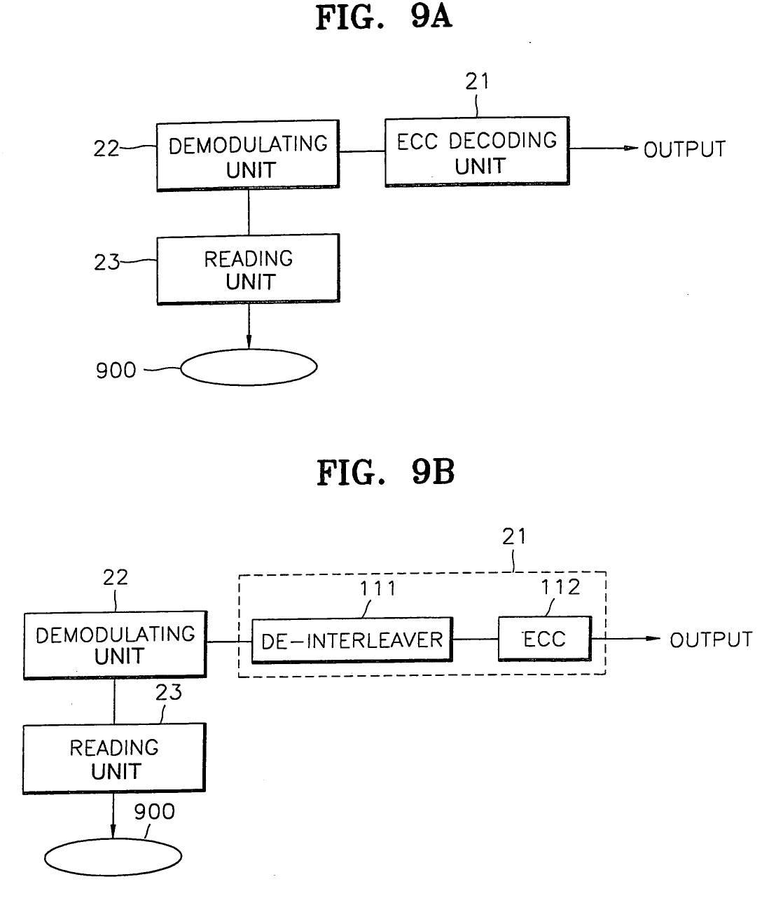

FIGS. 9A and 9B are block diagrams of a data reproducing apparatus according to the present invention. Referring to FIG. 9A, the data reproducing apparatus comprises a reading unit 23, a demodulating unit 22, and an ECC decoding unit 21. The reading unit 23 reads data from an optical disc 900 on which data is recorded according to the present invention. The demodulating unit 22 demodulates the read data. The demodulating method used depends on the modulating method.

The ECC decoding unit 21 ECC-decodes the demodulated data, that is, a recording block. More specifically, referring to FIG. 9B, the ECC decoding unit 21 includes a de-interleaver 111 and an ECC decoder 112. The de-interleaver 111 de-interleaves the recording block in the order reverse to the interleaver 12 of FIG. 1B to generate a plurality of error correction code (ECC) blocks. The ECC decoder 112 decodes the demodulated data into main data with an ECC, which are used in the generated ECC block, and outputs the main data.

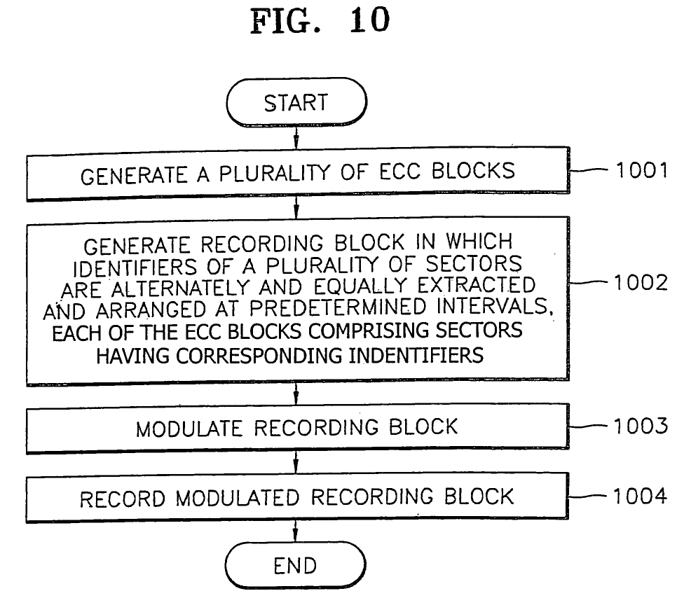

FIG. 10 is a schematic flow chart illustrating a data recording method according to an embodiment the present invention. Referring to FIG. 10, in operation 1001, an ECC encoder 11 ECC-encodes main data to generate a plurality of ECC blocks.

In operation 1002, an interleaver 12 generates a recording block in which identifiers of a plurality of sectors are alternately and equally extracted and arranged at predetermined intervals, each of the ECC blocks having sectors and each sector having an identifier. More specifically, identifiers in an ECC block and identifiers in the remaining ECC blocks are alternately and equally extracted and arranged at predetermined intervals in the recording block. The order of arrangement is decided such that the ECC blocks are alternately selected. The ECC-encoded main data included in the sectors corresponding to the arranged identifiers are interleaved to generate the recording block. Here, interleaving is performed in units of one or more rows, or in units of at least part of the sectors.

In operation 1003, the modulating unit 3 modulates the recording block. In operation 1004, a recording unit 5 records the modulated recording block on an optical disc 100.

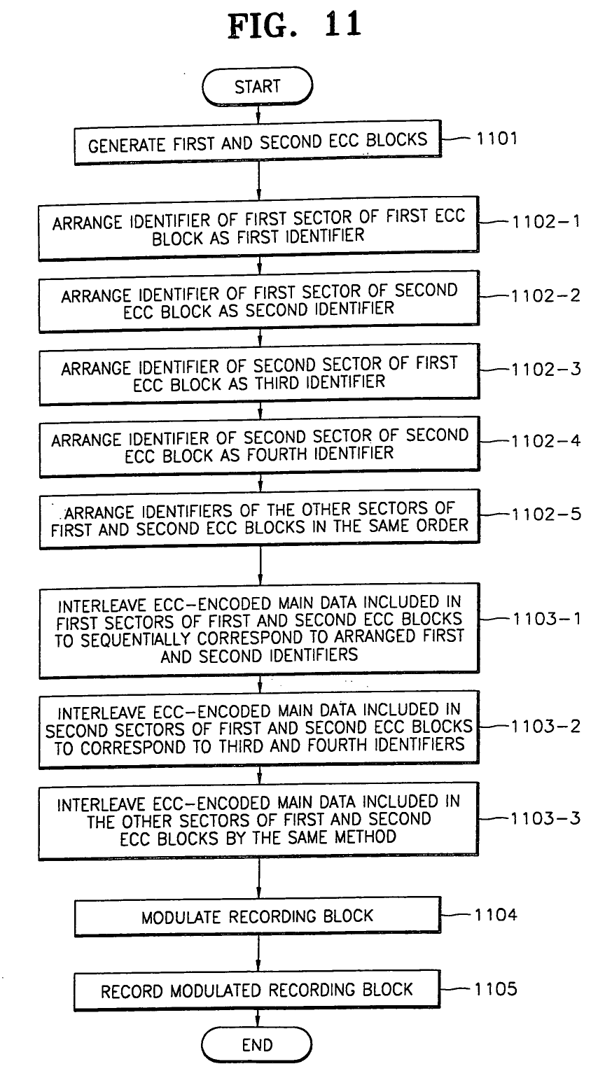

FIG. 11 is a flow chart illustrating a data recording method according to an embodiment of the present invention. Referring to FIG. 11, in operation 1101, the ECC encoder 11 ECC-encodes main data to generate first and second ECC blocks.

In operation 1102-1, the interleaver 12 arranges an identifier of the first sector of the first ECC block as a first identifier, arranges an identifier of the first sector of the second ECC block as a second identifier in operation 1102-2, arranges an identifier of the second sector of the first ECC block as a third identifier in operation 1102-3, arranges the identifier of a second sector of the second ECC block as a fourth identifier in operation 1102-4, and arranges identifiers of the remaining sectors of the first and second ECC blocks in the same order in operation 1102-5. Here, the interleaver 12 interleaves the ECC-encoded main data included in the first sectors of the first and second ECC blocks to sequentially correspond to the arranged first and second identifiers in operation 1103-1, interleaves the ECC-encoded main data included in the second sectors of the first and second ECC blocks to correspond to third and fourth identifiers in operation 1103-2, and interleaves the ECC-encoded main data included in the remaining sectors of the first and second ECC blocks by the same method in operation 1103-3, thereby generating the recording block.

In operation 1104, the modulating unit 3 modulates the recording block. In operation 1105, the recording unit 5 records the modulated recording block on the optical disc 100.

As described above, according to the present invention, the optical information recording medium, the data recording apparatus, and the data recording method used by the apparatus, which have higher error correction rates in recording and/or reading data, are provided. Further, according to the present invention, identifiers included in sectors are alternately and equally extracted and arranged in the recording block, thereby providing the ability to search main data at a high speed together with lower error rates. Furthermore, according to an embodiment of the present invention, an optical information recording medium, a data recording apparatus, and a data recording method used by the apparatus, which are compatible with the format of a conventional digital versatile disc (DVD) and have higher error correction rates, are provided. It is understood that a system which uses the present invention also includes permanent or removable storage, such as magnetic and optical discs, RAM, ROM, a carrier wave medium, etc., on which the process and data structures of the present invention can be stored and distributed. The operations can also be distributed via, for example, downloading over a network such as the Internet.

Although a few embodiments of the present invention have been shown and described, it will be appreciated by those skilled in the art that changes may be made in these embodiments without departing from the principles and spirit of the invention, the scope of which is defined in the appended claims and their equivalents.

What is claimed is:

1. An apparatus to record data on an optical information recording medium, the apparatus comprising:
an error correction code (ECC) encoder which ECC-encodes main data to generate a plurality of ECC blocks, each of the ECC blocks comprising sectors and each of the sectors having an identifier;
an interleaver which extracts and arranges the identifiers from ones of the ECC blocks to generate a recording block such that adjacent identifiers are of different ECC blocks;
a modulating unit which modulates the generated recording block; and
a recording unit which records the modulated recording block.

2. The apparatus according to claim 1, wherein said interleaver alternately and equally extracts and arranges the identifiers at predetermined intervals, and interleaves the ECC-encoded main data included in the sectors corresponding to the arranged identifiers.

3. The apparatus according to claim 2, wherein said interleaver performs the interleaving in units of one or more rows.

4. The apparatus according to claim 2, wherein said interleaver performs the interleaving in units of at least a part of the sectors.

5. An apparatus to record data on an optical information recording medium, the apparatus comprising:
an error correction code (ECC) encoder to ECC-encode main data to generate first and second ECC blocks, each of the first and second ECC blocks comprising sectors and each of the sectors includes an identifier;
an interleaver which arranges an identifier included in the first sector of the first ECC block as a first identifier, arranges an identifier included in the first sector of the second ECC block as a second identifier, arranges an identifier included in the second sector of the first ECC block as a third identifier, arranges an identifier included in the second sector of the second ECC block as a fourth identifier, arranging identifiers included in the remaining sectors of the first and second ECC blocks with the same algorithm, interleaves ECC-encoded main data in the first sectors of the first and second ECC blocks to sequentially correspond to the first arranged identifier and the second arranged identifier, interleaves ECC-encoded main data in the second sectors of the first and second ECC blocks to correspond to the third and fourth arranged identifiers, and interleaves ECC-encoded main data included in the remaining sectors of the first and second ECC blocks with the same algorithm to generate a recording block;
a modulating unit which modulates the generated recording block; and
a recording unit which records the modulated recording block.

6. The apparatus according to claim 5, wherein said interleaver alternately and equally extracts and arranges the identifiers at predetermined intervals.

7. The apparatus according to claim 6, wherein said interleaver performs the interleaving in units of one or more rows.

8. The apparatus according to claim 6, wherein said interleaver performs the interleaving in units of at least a part of the sectors.

9. An optical information reproducing apparatus comprising:
a reading unit to read data from a recording block of an optical information recording medium, wherein identifiers from ones of error correction code (ECC) blocks are alternately arranged in the recording block, each of the ECC blocks comprising a plurality of sectors having corresponding identifiers;
a demodulating unit to demodulate said read data; and
an ECC decoding unit to decode said de-modulated data.

10. The optical information reproducing apparatus according to claim 9, wherein said ECC decoding unit comprises:
a de-interleaver to de-interleave said recording block to generate a plurality of reproduced ECC blocks; and
an ECC decoder to decode said demodulated data into main data with an ECC and to output said main data.

11. The optical information reproducing apparatus according to claim 9, wherein said demodulation is performed depending on the modulation of said recording block.
